(19) United States
(12) Patent Application Publication
(10) Pub. No.: US 2024/0055307 A1
(43) Pub. Date: Feb. 15, 2024

(54) SEMICONDUCTOR PACKAGE AND METHOD OF MANUFACTURING SEMICONDUCTOR PACKAGE

(71) Applicant: SAMSUNG ELECTRONICS CO., LTD., Suwon-si (KR)

(72) Inventor: Sojeong HONG, Suwon-si (KR)

(21) Appl. No.: 18/338,037

(22) Filed: Jun. 20, 2023

(30) Foreign Application Priority Data
Aug. 11, 2022 (KR) 10-2022-0100281

(51) Int. Cl. H01L 23/18; H01L 23/31; H01L 23/29

(52) U.S. Cl. CPC H01L 23/18; H01L 23/3128; H01L 23/295

(57) ABSTRACT

A semiconductor package includes a package substrate, a first semiconductor chip and a second semiconductor chip on the package substrate in adjacent, spaced-apart relationship, a first molding member on the package substrate and covering the first semiconductor chip and the second semiconductor chip, and a second molding member on the first molding member. The first molding member includes a first molding portion on the first semiconductor chip and a second molding portion between the first and second semiconductor chips. A ratio per unit volume of filler material included in the first molding portion is greater than a ratio per unit volume of filler material included in the second molding portion.

### PRIORITY STATEMENT

This application claims priority under 35 U.S.C. § 119 to Korean Patent Application No. 10-2022-0100281, filed on Aug. 11, 2022 in the Korean Intellectual Property Office (KIPO), the contents of which are herein incorporated by reference in their entirety.

### BACKGROUND

### 1. Field

Example embodiments relate to semiconductor packages and methods of manufacturing semiconductor packages. More particularly, example embodiments relate to semiconductor packages including a plurality of semiconductor chips and methods of manufacturing the same.

### 2. Description of the Related Art

A semiconductor package, such as a memory product, may include a plurality of semiconductor chips spaced apart from each other on a package substrate. After the plurality of semiconductor chips are mounted on the package substrate, a molding member such as an epoxy mold compound (EMC) may be formed to protect the semiconductor chips from the surrounding environment, such as heat and moisture. The molding member may be formed by a compression mold, and a release film may be attached to the mold to prevent contamination of the mold. However, due to the roughness of the release film, a difference in content of filler material in the molding material may be transferred to a surface of the molding member, resulting in a visual variation between a semiconductor chip region and a surrounding region.

### SUMMARY

Example embodiments provide semiconductor packages having improved surface roughness, heat dissipation and strength characteristics.

Example embodiments provide methods of manufacturing semiconductor packages.

According to example embodiments, a semiconductor package includes a package substrate, a first semiconductor chip and a second semiconductor chip on the package substrate in adjacent, spaced-apart relationship, a first molding member on the package substrate and covering the first semiconductor chip and the second semiconductor chip, and a second molding member on the first molding member. The first molding member includes a first molding portion on the first semiconductor chip and a second molding portion between the first and second semiconductor chips. A ratio per unit volume of filler material included in the first molding portion is greater than a ratio per unit volume of filler material included in the second molding portion.

According to example embodiments, a semiconductor package includes a package substrate having a first mounting region and a second mounting region in adjacent spaced-apart relationship, a first semiconductor chip mounted on the first mounting region, and a second semiconductor chip mounted on the second mounting region, a first molding member on the package substrate covering the first semiconductor chip and the second semiconductor chip, the first molding member including a first cover portion covering the first semiconductor chip on the first mounting region and a second cover portion between the first and second mounting regions, and a second molding member on the first molding member. A ratio per unit volume of filler material included in the first cover portion is greater than a ratio per unit volume of filler material included in the second cover portion.

According to example embodiments, in a method of manufacturing a semiconductor package, a first semiconductor chip and a second semiconductor chip are mounted on a package substrate in adjacent, spaced-apart relationship. A molding apparatus having a first mold having a seating surface on which the package substrate is seated and a second mold to be engaged with the first mold to form a molding space for molding the first and second semiconductor chips is provided. The package substrate is adsorbed on the seating surface of the first mold. A release film is adsorbed on an adsorption surface of the second mold. A molding material is supplied into the molding space to form a first molding member on the package substrate. A second molding member is formed on the first molding member.

According to example embodiments, a semiconductor package may include a first semiconductor chip and a second semiconductor chip in adjacent, spaced-apart relationship on a package substrate, a first molding member on the package substrate to cover the first semiconductor chip and the second semiconductor chip, and a second molding member on the first molding member. The first molding member may include a first molding portion on each of the first and second semiconductor chips and a second molding portion between the first and second semiconductor chips.

A ratio per unit volume of filler material included in the first molding portion is greater than a ratio per unit volume of filler material included in the second molding portion. Due to this difference in content, the first and second cover portions may look different from each other when viewed from an upper surface of the first molding member.

Since the second molding member is formed on the entire upper surface of the first molding member, poor visibility due to the difference in content of the filler material between the first and second cover portions may be prevented. Further, depending on the physical properties of the second molding member, effects of heat dissipation and strength improvement may be obtained, and warpage of the entire package may be prevented or reduced.

### BRIEF DESCRIPTION OF THE DRAWINGS

Example embodiments will be more clearly understood from the following detailed description taken in conjunction with the accompanying drawings. FIGS. 1 to 10 represent non-limiting, example embodiments as described herein.

FIG. 1 is a plan view illustrating a semiconductor package in accordance with example embodiments.

FIG. 2 is a cross-sectional view taken along the line A-A′ in FIG. 1.

FIG. 3 is an enlarged cross-sectional view illustrating portion ‘B’ in FIG. 2.

FIG. 4 is an enlarged cross-sectional view illustrating portion ‘C’ in FIG. 2.

FIGS. 5 to 10 are views illustrating a method of manufacturing a semiconductor package in accordance with example embodiments.

### DETAILED DESCRIPTION OF EXAMPLE EMBODIMENTS

Hereinafter, example embodiments will be explained in detail with reference to the accompanying drawings.

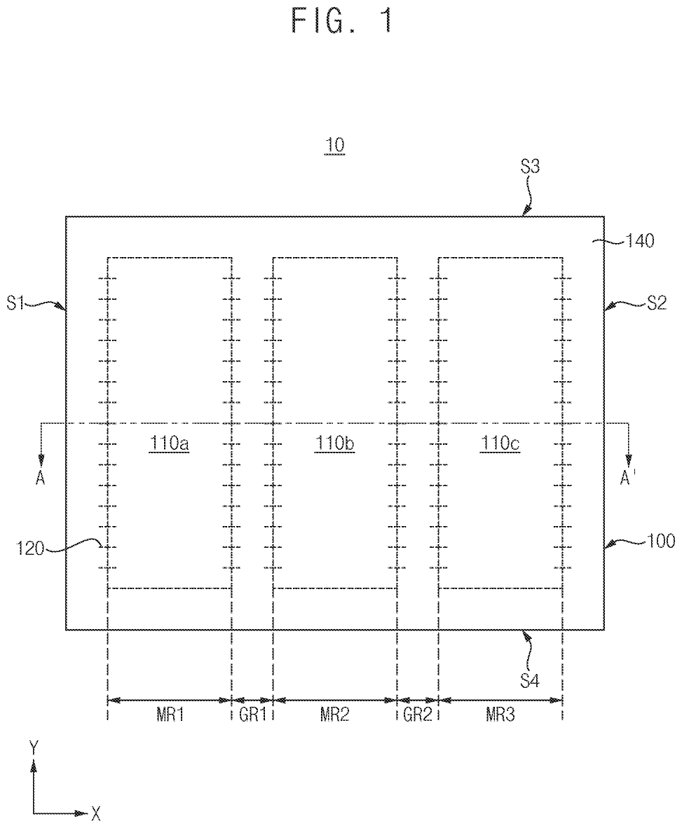

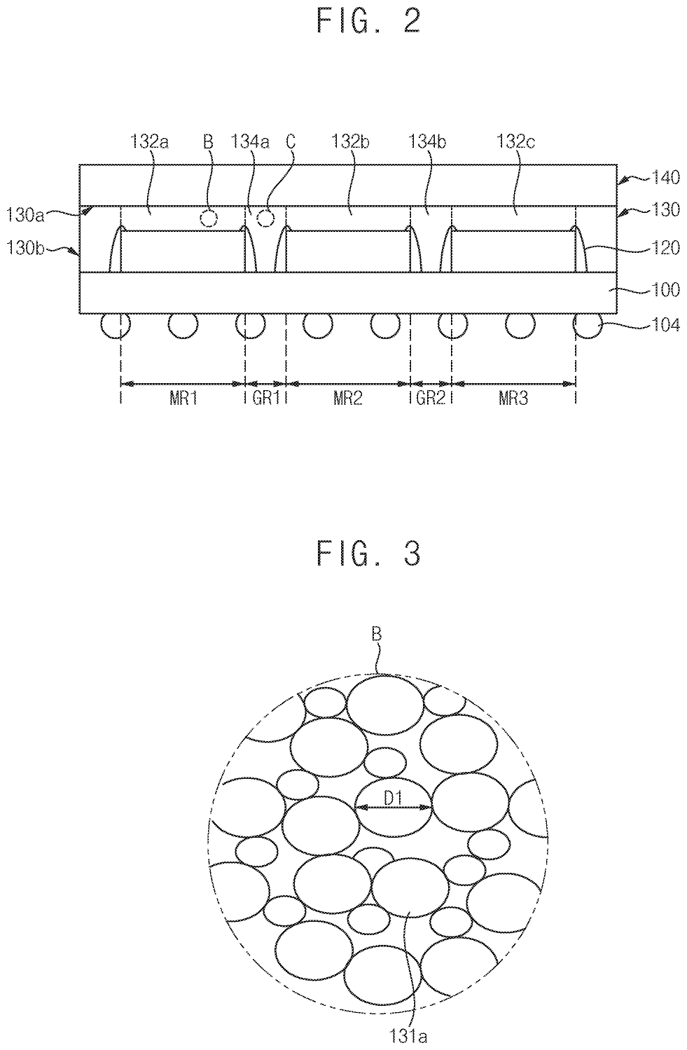

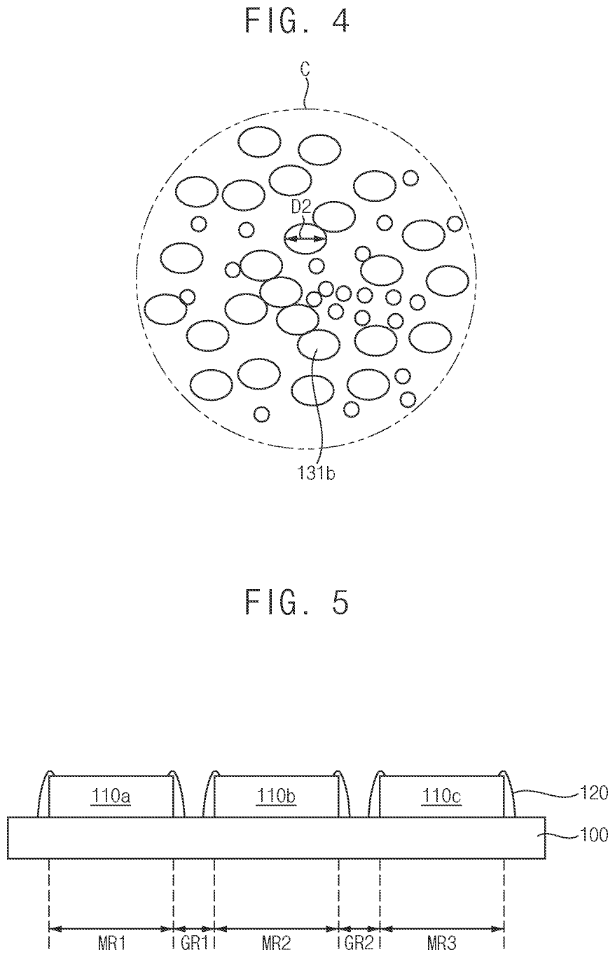

FIG. 1 is a plan view illustrating a semiconductor package in accordance with example embodiments. FIG. 2 is a cross-sectional view taken along the line A-A′ in FIG. 1. FIG. 3 is an enlarged cross-sectional view illustrating portion ‘B’ in FIG. 2. FIG. 4 is an enlarged cross-sectional view illustrating portion ‘C’ in FIG. 2.

Referring to FIGS. 1 to 4, a semiconductor package 10 may include a package substrate 100, semiconductor chips 110a, 110b and 110c spaced apart from each other on the package substrate 100, a first molding member 130 on the package substrate 100 to cover the semiconductor chips 110a, 110b and 110c, and a second molding member 140 disposed on the first molding member 130. In addition, the semiconductor package 10 may further include external connection members 104.

Additionally, the semiconductor package 10 may be provided as a multi-chip package (MCP) or a system in package (SIP). For example, the semiconductor chips may include a logic chip including a logic circuit and/or a memory chip. The logic chip may be a controller that controls memory chips. The memory chip may include various types of memory circuits, such as DRAM, SRAM, flash, PRAM, ReRAM, FeRAM, or MRAM.

In example embodiments, the package substrate 100 may be a substrate having upper and lower surfaces opposite to each other. For example, the package substrate 100 may be a printed circuit board (PCB). The printed circuit board may be a multilayer circuit board having vias and various circuits therein.

The package substrate 100 may include first to third mounting regions MR1, MR2 and MR3 spaced apart from each other and first and second gap regions GR1, GR2 between the first to third mounting regions MR1, MR2 and MR3. The package substrate 100 may have first and second side surfaces S1 and S2 facing away from each other and extending in a direction perpendicular to the upper surface and parallel to a second direction (Y direction) and a third side surface S3 and a fourth side surface S4 facing away from each other and extending in a direction parallel to a first direction (X direction) perpendicular to the second direction. For example, a width of the package substrate in the first direction (X direction) may be within a range of 10 mm to 15 mm, and a width of each of the first to third mounting regions MR1, MR2 and MR3 in the first direction (X direction) may be within a range of 3 mm to 4 mm.

In example embodiments, the first semiconductor chip 110a may be disposed on the first mounting region MR1. The second semiconductor chip 110b may be disposed on the second mounting region MR2. The third semiconductor chip 110c may be disposed on the third mounting region MR3. The first to third semiconductor chips 110a, 110b and 110c may be attached on the package substrate 100 using an adhesive film such as direct adhesive film (DAF).

A wire bonding process may be performed to electrically connect the first to third semiconductor chips 110a, 110b and 110c to the package substrate 100. Chip pads of the first to third semiconductor chips 110a, 110b and 110c may be connected to substrate pads on the upper surface of the package substrate 100 by conductive connection members, that is, bonding wires 120.

For example, a width of the first gap region GR1, i.e., a spacing distance between the first and second semiconductor chips 100a and 100b, and a width of the second gap region GR2, i.e., a spacing distance between the second and third semiconductor chips 100b and 100c may be within a range of 0.3 mm to 0.5 mm. A width of each of the first to third semiconductor chips 110a, 110b and 110c may be within a range of 3 mm to 4 mm.

The first semiconductor chip 110a may have a first height from the upper surface of the package substrate 100, the second semiconductor chip 110b may have a second height from the upper surface of the package substrate 100, and the third semiconductor chip 110c may have a third height from the upper surface of the package substrate 100. The first height, the second height and the third height may be different from each other. For example, the first height may be greater than the second height, and the second height may be greater than the third height. Alternatively, the first height may be the same as the second height, and the second height may the same as the third height.

The number, size, arrangement, etc., of the first to third semiconductor chips are provided as examples, and it will be understood that it may not be limited thereto. For example, a plurality of first semiconductor chips, a plurality of second semiconductor chips, and a plurality of third semiconductor chips may be sequentially stacked on the package substrate 100. In addition, wirings in the package substrate as well as the substrate pads and the chip pads are well known in the art to which the present invention pertains, and thus illustration and description thereof will be omitted.

In other embodiments, at least one of the semiconductor chips 110a, 110b and 110c may be mounted on the package substrate 100 using a flip chip bonding method. The semiconductor chip may be electrically connected to the package substrate 100 via conductive bumps.

In this case, the conductive bumps may be respectively disposed on the substrate pads on the upper surface of the package substrate 100 to connect the semiconductor chip and the package substrate 100. When the semiconductor chip is bonded to the package substrate 100, an adhesive may be underfilled between the semiconductor chip and the package substrate 100. The adhesive may include an epoxy material to reinforce a gap between the semiconductor chip and the package substrate 100.

In example embodiments, the first molding member 130 may be formed on the package substrate 100 to protect the first semiconductor chips 110a, 110b and 110c and the bonding wires 120 from the outside (i.e., from an external environment). The first molding member may include an epoxy molding compound (EMC).

The first molding member may include filler material 131a (FIG. 3) and filler material 131b (FIG. 4) and an epoxy resin serving as a binder for the filler material 131a, 131b. The filler material 131a, 131b may be within a range of 60 wt % to 95 wt % of the total weight of the first molding member 130. The epoxy resin may be within a range of 5 wt % to 20 wt % of the total weight of the first molding member 130. The filler material 131a, 131b may include silica (SiO₂). The maximum diameter of a particle of the filler material 131a, 131b may be 45 μm. The filler material 131a, 131b may control the fluidity of EMC and improve flexural strength.

As illustrated in FIG. 2, the first molding member 130 may include first, third and fifth molding portions 132a, 132b and 132c on the first to third semiconductor chips 110a, 110b and 110b, a second molding portion 134a between the first and second semiconductor chips 110a and 110b and a fourth molding portion 134b between the second and third semiconductor chips 110b and 110c. The first molding member 130 may have a flat upper surface 130a.

The first, third and fifth molding portions 132a, 132b, and 132c may be referred to as first cover portions respectively formed on the semiconductor chips, and the second and fourth molding portions 134a and 134b may be referred to as second cover portions respectively formed between the semiconductor chips. The first molding member 130 may include the first cover portion and the second cover portion integrally formed with each other.

As illustrated in FIGS. 3 and 4, an occupancy ratio per unit volume occupied by the filler material 131a included in each of the first, third and fifth molding portions 132a, 132b and 132c may be greater than an occupancy ratio per unit volume occupied by the filler material 131b included in each of the second and fourth molding portions 134a and 134b. The occupancy ratio per unit volume occupied by the filler material 131a included in each of the first, third and fifth molding portions 132a, 132b and 132c may be within a range of 50% to 70%, and the occupancy ratio per unit volume occupied by the filler material 131b included in each the second and fourth molding portions 134a an 134b may be within a range of 30% to 55%. In other words, the filler material 131a accounts for between 50% to 70% of the volume of each of the first, third and fifth molding portions 132a, 132b and 132c, and the filler material 131b accounts for between 30% to 55% of the volume of each of the second and fourth molding portions 134a, 134b. An average particle size of the filler material 131a included in each of the first, third and fifth molding portions 132a, 132b and 132c may be greater than an average particle size of the filler material 131b included in each of the second and fourth molding portions 134a and 134b.

The second and fourth molding portions 134a and 134b on the first and second gap regions GR1 and GR2 of the package substrate 100 may extend in one direction between the first, third and fifth molding portions 132a, 132b and 132c. Since the content and average particle size of the filler material 131b in the second and fourth molding portions 134a and 134b are different from those of the filler material 131a in the first, third and fifth molding portions 132a, 132b and 132c, when viewed from the upper surface of the first molding member 130, a visual variation may occur such that the second and fourth molding portions 134a and 134b look different from the first, third and fifth molding portions 132a, 132b and 132c.

In example embodiments, the second molding member 140 may be disposed on the first molding member 130. The second molding member 140 may cover the entire upper surface 130a of the first molding member 130. A side surface 130b of the first molding member 130 may be exposed to the outside.

The second molding member 140 may include a material different from that of the first molding member 130. A thermal conductivity of the second molding member 140 may be greater than that of the first molding member 130. Alternatively, the second molding member 140 may include the same material as the first molding member 130.

Since the second molding member 140 is formed on the entire upper surface of the first molding member 130, poor visibility may be prevented. Depending on the physical properties of the second molding member 140, effects of heat dissipation and strength improvement may be obtained. Further, warpage of the entire package may be prevented or reduced by the second molding member 140.

In example embodiments, external connection pads for providing electrical signals may be formed on the lower surface of the package substrate 100. The external connection pads may be exposed by an insulating layer. The insulating layer may include a silicon oxide layer, a silicon nitride layer, or a silicon oxynitride layer. An external connection member 104 for electrical connection with an external device may be disposed on the external connection pad of the package substrate 100. For example, the external connection member 104 may be a solder ball. The semiconductor package 10 may be mounted on a module substrate (not illustrated) via the solder balls to form a memory module.

As mentioned above, the semiconductor package 10 may include the first molding member 130 on the package substrate 100 covering the plurality of semiconductor chips 110a, 110b and 110c spaced apart from each other, and the second molding member 140 disposed on the first molding member 130. The first molding member 130 may include the first cover portion on each of the semiconductor chips 110a, 110b and 110c and the second cover portion between the semiconductor chips.

The occupancy ratio per unit volume occupied by the filler material 131a included in the first cover portion may be greater than the occupancy ratio per unit volume occupied by the filler material 131b included in the second cover portion. Due to this difference in content, the first and second cover portions may appear to be distinguished from each other when viewed from the upper surface of the first molding member 130.

Since the second molding member 140 is formed on the entire upper surface of the first molding member 130, poor visibility due to the difference in content of filler material between the first and second cover portions may be prevented. Depending on the physical properties of the second molding member 140, effects of heat dissipation and strength improvement may be obtained, and warpage of the entire package may be prevented or reduced.

Hereinafter, a method of manufacturing the semiconductor package in FIG. 1 will be explained.

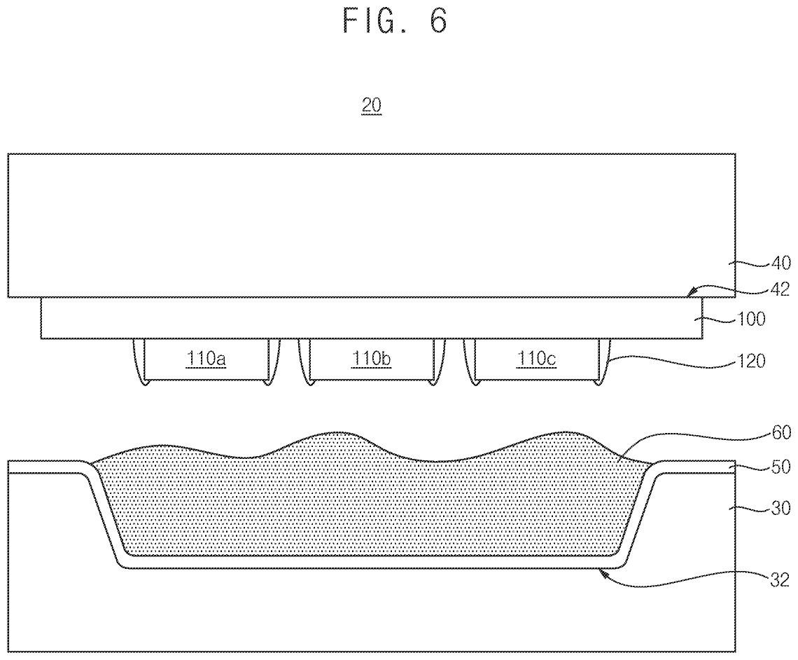

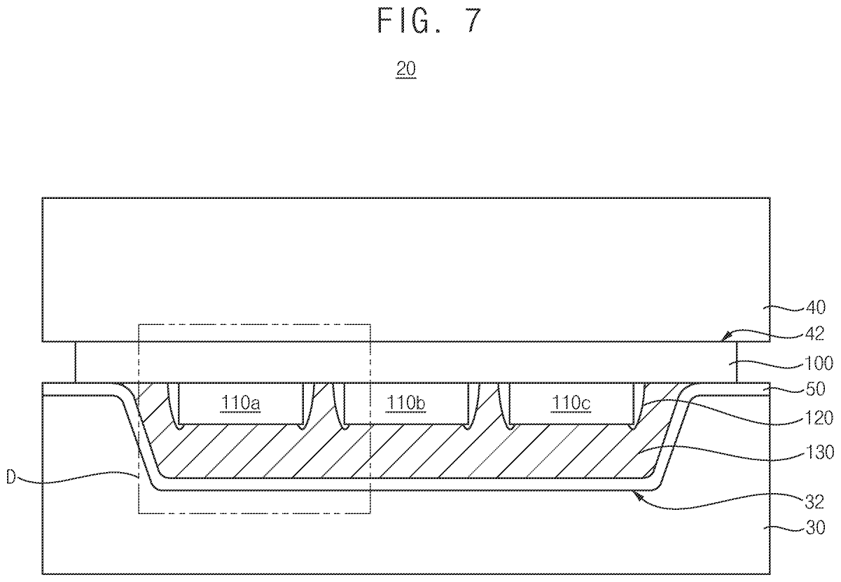

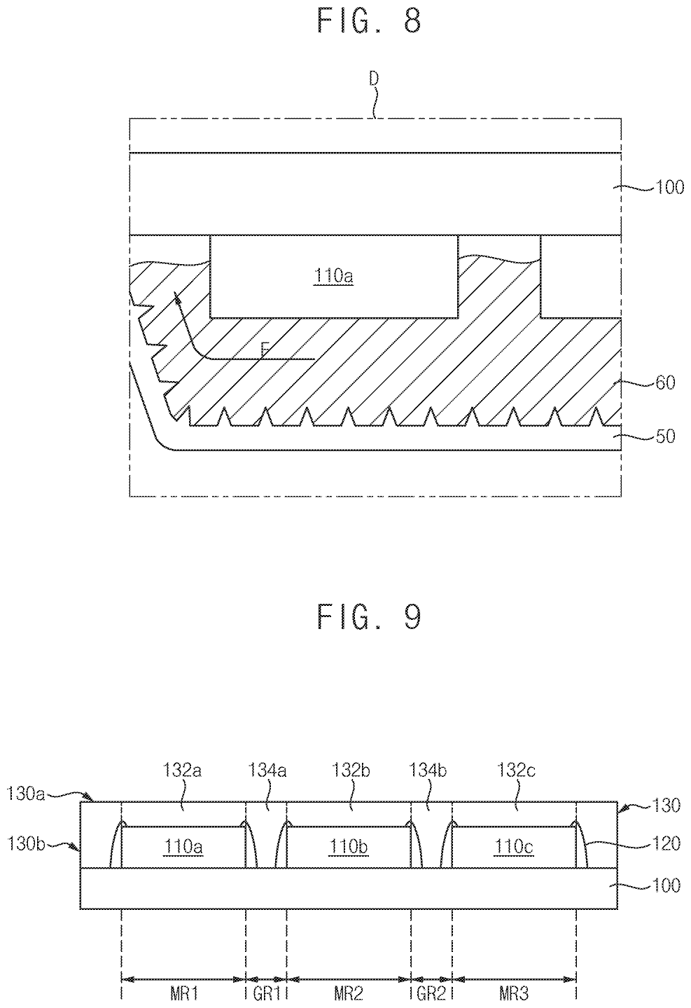

FIGS. 5 to 10 are views illustrating a method of manufacturing a semiconductor package in accordance with example embodiments. FIGS. 6 to 8 are views illustrating a process of forming a first molding member on a package substrate by using a molding apparatus. FIG. 8 is an enlarged cross-sectional view illustrating portion ‘D’ in FIG. 7.

Referring to FIG. 5, a plurality of semiconductor chips 110a, 100b and 100c may be mounted on the package substrate 100 to be spaced apart from each other.

In example embodiments, the package substrate 100 may include first to third mounting regions MR1, MR2 and MR3 spaced apart from each other and first and second gap regions GR1 and GR2 between the first to third mounting regions MR1, MR2 and MR3. The first semiconductor chip 110a may be disposed on the first mounting region MR1. The second semiconductor chip 110b may be disposed on the second mounting region MR2. The third semiconductor chip 110c may be disposed on the third mounting region MR3. The first to third semiconductor chips 110a, 110b and 110c may be attached on the package substrate 100 using an adhesive film such as direct adhesive film (DAF).

For example, the first to third semiconductor chips 110a, 110b and 110c may include a logic chip including a logic circuit or a volatile memory device such as DRAM. The semiconductor chip may be a controller that controls memory chips.

A wire bonding process may be performed to electrically connect the first to third semiconductor chips 110a, 110b and 110c to the package substrate 100. Chip pads of the first to third semiconductor chips 110a, 110b and 110c may be connected to substrate pads on an upper surface of the package substrate 100 by conductive connection members, that is, bonding wires 120.

For example, a width of the first gap region GR1, i.e., a spacing distance between the first and second semiconductor chips 100a and 100b, and a width of the second gap region GR2, i.e., a spacing distance between the second and third semiconductor chips 100b and 100c may be within a range of 0.3 mm to 0.5 mm. A width of each of the first to third semiconductor chips 110a, 110b and 110c may be within a range of 3 mm to 4 mm. However, the number, size, arrangement, etc., of the first to third semiconductor chips are provided as examples, and it will be understood that it may not be limited thereto. For example, a plurality of first semiconductor chips, a plurality of second semiconductor chips and a plurality of third semiconductor chips may be sequentially stacked on the package substrate 100.

Referring to FIGS. 6 to 9, a first molding member 130 may be formed on the package substrate 100 to cover the first to third semiconductor chips 110a, 110b and 110c.

In example embodiments, the first molding member 130 may be formed by a compression mold process. By using a compression mold, it may be possible to prevent the bonding wires 120 from being swept. Alternatively, the first molding member may be formed by a transfer mold process.

As illustrated in FIG. 6, a molding apparatus 20 including a first mold 40 having a seating surface 42 on which the package substrate 100 is seated and a second mold 30 to be engaged with the first mold 40 to form a molding space for the molding of the semiconductor chips 110a, 110b and 110c may be provided. The package substrate 100 may be adsorbed (i.e., held) on the seating surface 42 of the first mold 40, and a release film 50 may be adsorbed (i.e., held) on an adsorption surface 32 of the second mold 30, and a molding material 60 may be supplied on the release film 50 in a cavity of the second mold 30. For example, the molding material 60 may include an epoxy molding compound (EMC) in powder form. The release film 50 may omit a cleaning process of the mold and minimize foreign matters in the mold.

As illustrated in FIG. 7, the molding material 60 in the cavity of the second mold 30 may be heated and melted, and the first mold 40 and the second mold 30 may be engaged such that the semiconductor chips 110a, 110b, 110c on the package substrate 100 are immersed in molten resin to perform the compression mold process.

As illustrated in FIG. 8, shear stress may be exerted on a surface of the release film 50 by the mold flow F generated during the compression molding, so that the release film 50 may have surface roughness. Due to the surface roughness of the release film 50, a difference in filler material content of the molding material may occur between regions on the semiconductor chips 110a, 110b and 110b and surrounding regions.

The molding material may include filler material and an epoxy resin serving as a binder for the filler material. The filler material may be within a range of 60 wt % to 95 wt % of the total weight of the molding material. The filler material may include silica (SiO₂). The maximum diameter of the filler material may be 45 μm. The filler material may control the fluidity of EMC and improve flexural strength.

Among the filler materials, those with relatively good mobility (having a relatively large diameter) may be well filled in the upper regions over the semiconductor chips, and those with low mobility (having a relatively small diameter) may be well filled in the region between the semiconductor chips.

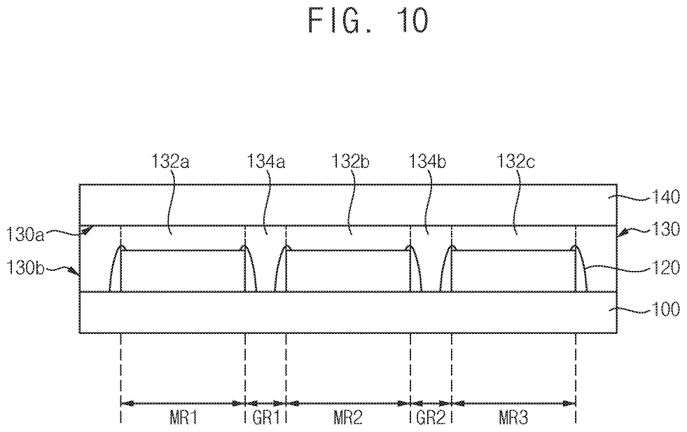

As illustrated in FIG. 9, the first molding member 130 may include first, third and fifth molding portions 132a, 132b and 132c on the first to third semiconductor chips 110a, 110b and 110b, a fourth molding portion 134a between the first and second semiconductor chips 110a and 110b, and a fifth molding portion 134b between the second and fourth semiconductor chips 110b and 110c. The first molding member 130 may have a flat upper surface 130a.

The first, third and fifth molding portions 132a, 132b and 132c may be referred to as first cover portions respectively formed on the semiconductor chips, and the second and fourth molding portions 134a and 134b may be referred to as second cover portions respectively formed between the semiconductor chips. The first molding member 130 may include the first cover portion and the second cover portion integrally formed from the first cover portion.

An occupancy ratio per unit volume occupied by the filler material included in each of the first, third and fifth molding portions 132a, 132b and 132c may be greater than an occupancy ratio per unit volume occupied by the filler material included in each of the second and fourth molding portions 134a and 134b. The occupancy ratio per unit volume occupied by the filler material included in each of the first, third and fifth molding portions 132a, 132b and 132c may be within a range of 50% to 70%, and the occupancy ratio per unit volume occupied by the filler material included in each the second and fourth molding portions 134a an 134b may be within a range of 30% to 55%. An average particle size of the filler material included in each of the first, third and fifth molding portions 132a, 132b and 132c may be greater than an average particle size of the filler material included in each of the second and fourth molding portions 134a and 134b.

The second and fourth molding portions 134a and 134b on the first and second gap regions GR1 and GR2 of the package substrate 100 may extend in one direction between the first, third and fifth molding portions 132a, 132b and 132c. Since the content and average particle size of the filler material in the second and fourth molding portions 134a and 134b are different from those of the first, third and fifth molding portions 132a, 132b and 132c, when viewed from the upper surface of the first molding member 130, the second and fourth molding portions 134a and 134b may be distinguished from the first, third and fifth molding portions 132a, 132b and 132c (visual variations).

Referring to FIG. 10, a second molding member 140 may be formed on the first molding member 130.

In example embodiments, the second molding member 140 may be formed by a compression molding process or a transfer molding process. The second molding member 140 may cover the entire upper surface 130a of the first molding member 130. A side surface 130b of the first molding member 130 may be exposed to the outside.

The second molding member 140 may include a material different from that of the first molding member 130. A thermal conductivity of the second molding member 140 may be higher than that of the first molding member 130. Alternatively, the second molding member 140 may include the same material as the first molding member 130.

Since the second molding member 140 is formed on the entire upper surface of the first molding member 130, the poor visibility may be prevented. Depending on the physical properties of the second molding member 140, effects of heat dissipation and strength improvement may be obtained. Further, warpage of the entire package may be prevented by the second molding member 140.

External connection members 104 such as solder balls may be disposed on the external connection pads on a lower surface of the package substrate 100 to complete the semiconductor package 10 of FIG. 1.

The above semiconductor package may include semiconductor devices such as logic devices or memory devices. The semiconductor package may include logic devices such as central processing units (CPUs), main processing units (MPUs), or application processors (APs), or the like, and volatile memory devices such as DRAM devices, HBM devices, or non-volatile memory devices such as flash memory devices, PRAM devices, MRAM devices, ReRAM devices, or the like.

The foregoing is illustrative of example embodiments and is not to be construed as limiting thereof. Although a few example embodiments have been described, those skilled in the art will readily appreciate that many modifications are possible in example embodiments without materially departing from the novel teachings and advantages of the present invention. Accordingly, all such modifications are intended to be included within the scope of example embodiments as defined in the claims.

What is claimed is:

1. A semiconductor package, comprising:
a package substrate;
a first semiconductor chip and a second semiconductor chip on the package substrate in adjacent, spaced-apart relationship;
a first molding member on the package substrate and covering the first semiconductor chip and the second semiconductor chip; and
a second molding member on the first molding member,
wherein the first molding member comprises a first molding portion on the first semiconductor chip and a second molding portion between the first and second semiconductor chips, and
wherein a ratio per unit volume of filler material included in the first molding portion is greater than a ratio per unit volume of filler material included in the second molding portion.

2. The semiconductor package of claim 1, wherein an average particle size of the filler material included in the first molding portion is greater than an average particle size of the filler material included in the second molding portion.

3. The semiconductor package of claim 1, wherein the ratio per unit volume of the filler material included in the first molding portion is within a range of 50% to 70%, and the ratio per unit volume of the filler material included in the second molding portion is 30% to 55%.

4. The semiconductor package of claim 1, wherein the filler material included in the first molding member is within a range of 60 wt % to 95 wt % of a total weight of the first molding member.

5. The semiconductor package of claim 1, wherein the first molding member further comprises a third molding portion on the second semiconductor chip, and wherein a ratio per unit volume of filler material included in the third molding portion is greater than the ratio per unit volume of the filler material included in the second molding portion.

6. The semiconductor package of claim 1, wherein the second molding member covers an entire upper surface of the first molding member.

7. The semiconductor package of claim 6, wherein a side surface of the first molding member is exposed.

8. The semiconductor package of claim 1, wherein the second molding member comprises similar material as the first molding member.

9. The semiconductor package of claim 1, wherein the second molding member comprises a material different from a material of the first molding member.

10. The semiconductor package of claim 1, wherein a thermal conductivity of the second molding member is greater than a thermal conductivity of the first molding member.

11. A semiconductor package, comprising:
a package substrate comprising a first mounting region and a second mounting region in adjacent, spaced-apart relationship;
a first semiconductor chip mounted on the first mounting region, and a second semiconductor chip mounted on the second mounting region;
a first molding member on the package substrate covering the first semiconductor chip and the second semiconductor chip, wherein the first molding member comprises a first cover portion covering the first semiconductor chip on the first mounting region and a second cover portion between the first and second mounting regions; and
a second molding member on the first molding member,
wherein a ratio per unit volume of filler material included in the first cover portion is greater than a ratio per unit volume of filler material included in the second cover portion.

12. The semiconductor package of claim 11, wherein an average particle size of the filler material included in the first cover portion is greater than an average particle size of the filler material included in the second cover portion.

13. The semiconductor package of claim 11, wherein the ratio per unit volume of the filler material included in the first cover portion is within a range of 50% to 70%, and the ratio per unit volume of the filler material included in the second cover portion is 30% to 55%.

14. The semiconductor package of claim 11, wherein the second molding member covers an entire upper surface of the first molding member.

15. The semiconductor package of claim 14, wherein a side surface of the first molding member is exposed.

16. The semiconductor package of claim 11, wherein the second molding member comprises similar material as the first molding member.

17. The semiconductor package of claim 11, wherein the second molding member comprises a material different from that of the first molding member.

18. The semiconductor package of claim 11, wherein a thermal conductivity of the second molding member is greater than a thermal conductivity of the first molding member.

19. The semiconductor package of claim 11, wherein the first molding member comprises an epoxy molding compound.

20. A semiconductor package, comprising:
a package substrate comprising a first mounting region and a second mounting region in adjacent, spaced-apart relationship;
a first semiconductor chip mounted on the first mounting region, and a second semiconductor chip mounted on the second mounting region;
a first molding member on the package substrate covering the first semiconductor chip and the second semiconductor chip, wherein the first molding member comprises a first cover portion covering the first semiconductor chip on the first mounting region and a second cover portion between the first and second mounting regions; and
a second molding member on the first molding member,
wherein a ratio per unit volume of filler material included in the first cover portion is greater than a ratio per unit volume of filler material included in the second cover portion, and
wherein a spacing distance between the first and second semiconductor chips is within a range of 0.3 mm to 0.5 mm
